(19) United States
(12) Patent Application Publication
(10) Pub. No.: US 2026/0059911 A1
(43) Pub. Date: Feb. 26, 2026

(54) Display Device and Transfer Device for Fabricating Display Device

(71) Applicant: LG Display Co., Ltd., Seoul (KR)

(72) Inventor: YeongSoo Nam, Uijeongbu-si (KR)

(21) Appl. No.: 19/084,212

(22) Filed: Mar. 19, 2025

(30) Foreign Application Priority Data
Aug. 21, 2024 (KR) 10-2024-0111952

(51) Int. Cl. H10H 29/03; H10H 29/39

(52) U.S. Cl. CPC H10H 29/03; H10H 29/39

(57) ABSTRACT

A transfer device is configured to transfer a plurality of micro LEDs of a wafer onto a target substrate and includes a light source configured to output light; a digital mirror device including a plurality of micro mirrors configured to reflect light from the light source; and an optical system configured to correct a plurality of light reflected from the plurality of micro mirrors to be transmitted to the wafer, and each of the plurality of light reflected from each of the plurality of micro LEDs is configured to be irradiated onto a wafer so as to correspond to each of the plurality of micro LEDs of the wafer. Accordingly, a digital mirror device which irradiates light onto each of the plurality of micro LEDs is provided to simultaneously transfer the plurality of micro LEDs.

### CROSS-REFERENCE TO RELATED APPLICATION

This application claims the priority of Republic of Korea Patent Application No. 10-2024-0111952 filed on Aug. 21, 2024, which is hereby incorporated by reference in its entirety.

### BACKGROUND

### Field

The present disclosure relates to a display device and a transfer device for fabricating a display device.

### Description of the Related Art

Display devices are being applied to various electronic devices, such as televisions (TVs), mobile phones, notebooks, and tablets.

As display devices, there are an organic light emitting display (OLED) which is a self-emitting device and a liquid crystal display (LCD) which requires a separate light source.

In recent years, a display device including a micro light emitting diode (mLED or μLED) as a light emitting element is attracting attention as a next generation display device. The micro LED is formed of an inorganic material, rather than an organic material so that lighting speed is faster, a luminous efficiency is excellent, and an image with a higher luminance is displayed, as compared with the liquid crystal display or the organic light emitting display.

### SUMMARY

An object to be achieved by the present disclosure is to provide a display device with a simplified structure of a plurality of pixel circuits.

Another object to be achieved by the present disclosure is to provide a display device in which a plurality of pixel circuits is integrated in one pixel driving circuit to be driven at a low power and the power consumption is reduced.

Still another object to be achieved by the present disclosure is to provide a transfer device which simultaneously transfers a plurality of micro LEDs.

Still another object to be achieved by the present disclosure is to provide a transfer device which may transfer a plurality of micro LEDs in a contactless manner to minimize influence of the flatness of a wafer and a target substrate.

Still another object to be achieved by the present disclosure is to provide a transfer device which precisely adjusts an irradiation area, a diameter, and a pitch of a plurality of light.

Still another object to be achieved by the present disclosure is to provide a transfer device which adjusts a pitch of a plurality of light.

Objects of the present disclosure are not limited to the above-mentioned objects, and other objects, which are not mentioned above, can be clearly understood by those skilled in the art from the following descriptions.

According to an embodiment of the present disclosure, a transfer device is a transfer device configured to transfer a plurality of micro LEDs of a wafer onto a target substrate and includes a light source configured to output light; a digital mirror device including a plurality of micro mirrors configured to reflect light from the light source; and an optical system configured to correct a plurality of light reflected from the plurality of micro mirrors to be transmitted to the wafer, and each of the plurality of light reflected from each of the plurality of micro LEDs is configured to be irradiated onto a wafer so as to correspond to each of the plurality of micro LEDs of the wafer. Accordingly, a digital mirror device which irradiates light onto each of the plurality of micro LEDs is provided to simultaneously transfer the plurality of micro LEDs.

According to another embodiment of the present disclosure, a display device includes a substrate in which a plurality of pixels is defined; one or more pixel driving circuits disposed on the substrate; a plurality of micro LEDs which is disposed on the plurality of pixels and is electrically connected to the pixel driving circuit; a plurality of banks disposed below the plurality of micro LEDs; and a plurality of first electrodes which is disposed between the plurality of micro LEDs and the plurality of banks and is configured to electrically connect the pixel driving circuit and the plurality of micro LEDs. Accordingly, circuits for driving the plurality of micro LEDs are integrated in one pixel driving circuit so that a structure of the display device may be simplified.

Other detailed matters of the exemplary embodiments are included in the detailed description and the drawings.

According to the present disclosure, the plurality of pixel circuits is integrated in one pixel driving circuit to be efficiently driven at a lower power.

According to the present disclosure, the plurality of micro LEDs is simultaneously transferred to shorten a process time and optimize the process.

According to the present disclosure, the plurality of micro LEDs is transferred in a contactless manner to minimize or at least reduce a process error according to a flatness of a wafer and a target substrate.

According to the present disclosure, an irradiation area, a diameter, and a pitch of a plurality of light are precisely adjusted to improve a transfer yield of the plurality of micro LEDs.

According to the present disclosure, pitches of the plurality of light are freely variable and a transfer process may be performed in accordance with wafers and target substrates with various disclosures.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view illustrating a display device according to an exemplary embodiment of the present disclosure;

FIG. 2 is a plan view of a display device according to an exemplary embodiment of the present disclosure;

FIG. 3 is an enlarged view of a display device according to an exemplary embodiment of the present disclosure;

FIG. 4 is a view illustrating a circuit structure according to an exemplary embodiment of the present disclosure;

FIGS. 5 to 7 are plan views of a display device according to an exemplary embodiment of the present disclosure;

FIG. 8 is a cross-sectional view of a display device according to an exemplary embodiment of the present disclosure;

FIG. 9 is a cross-sectional view of a display device according to an exemplary embodiment of the present disclosure;

FIG. 10 is a process flowchart for explaining a fabricating method of a display device according to an exemplary embodiment of the present disclosure;

FIG. 11 is a diagram illustrating a transfer device according to an exemplary embodiment of the present disclosure;

FIG. 12 is a schematic cross-sectional view of an optical system of a transfer device according to an exemplary embodiment of the present disclosure;

FIGS. 13 and 14 are cross-sectional views for explaining a fabricating method of a display device according to an exemplary embodiment of the present disclosure;

FIG. 15 is a process flowchart for explaining a fabricating method of a display device according to another exemplary embodiment of the present disclosure;

FIG. 16 is a diagram illustrating a transfer device according to another exemplary embodiment of the present disclosure;

FIGS. 17A to 17C are diagrams of a pitch correction unit of a transfer device according to another exemplary embodiment of the present disclosure;

FIG. 18 is a diagram illustrating a transfer device according to still another exemplary embodiment of the present disclosure; and

FIG. 19 is a diagram illustrating a micro lens array of a transfer device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When explaining temporal relationships, terms such as “after,” “following,” “subsequent to,” or “before,” etc., may include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Hereinafter, an exemplary embodiment of the present disclosure will be described in detail with reference to the drawings.

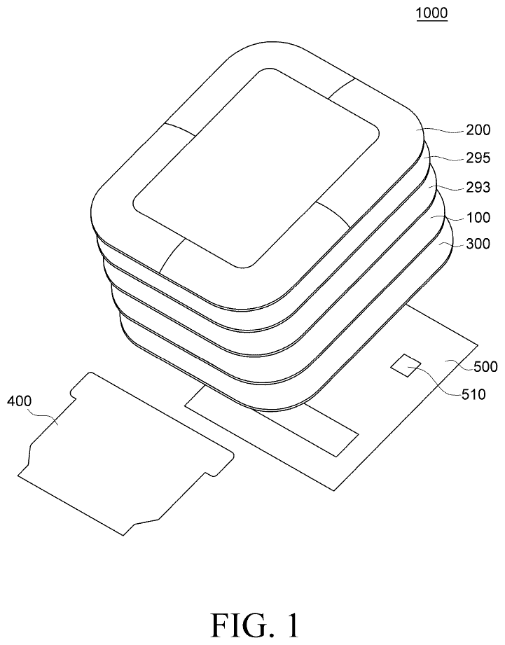

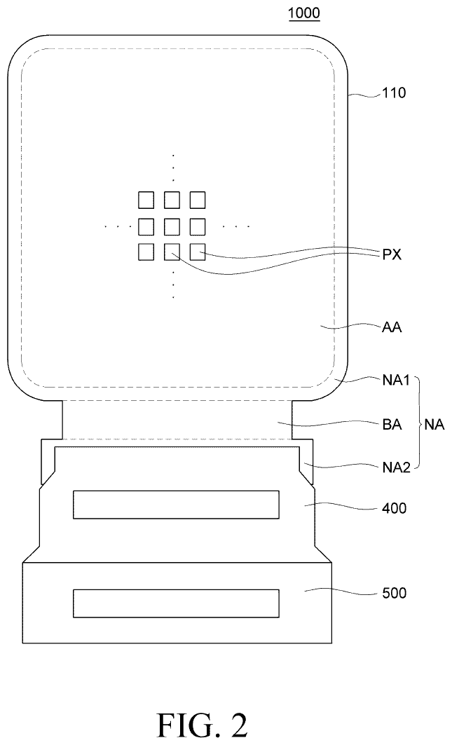

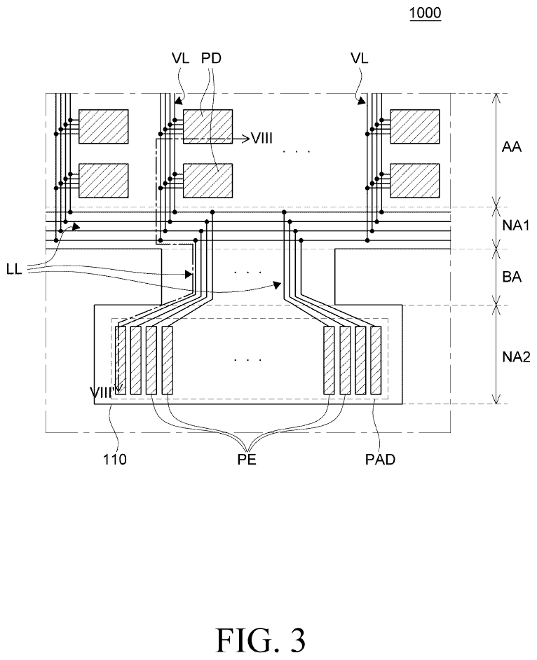

FIG. 1 is a perspective view illustrating a display device according to an exemplary embodiment of the present disclosure. FIG. 2 is a plan view of a display device according to an exemplary embodiment of the present disclosure. FIG. 3 is an enlarged view of a display device according to an exemplary embodiment of the present disclosure.

Referring to FIGS. 1 to 3, a display device 1000 according to an exemplary embodiment of the present disclosure may include a display panel 100, a polarization layer 293, a cover member 200, a support substrate 300, a flexible circuit board 400, and a printed circuit board 500.

For example, the display panel 100 of the display device 1000 may include a substrate 110. The substrate 110 may be a member which supports other components of the display device 1000. The substrate 110 may be formed of an insulating material, for example, glass or resin. Further, the substrate 110 may be formed of a material having flexibility, such as polyimide (PI). However, the exemplary embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA. However, the active area AA and the non-active area NA are not mentioned to be limited to the substrate 110, but mentioned for the entire display device 1000.

The active area AA is an area where images are displayed. The active area AA includes a plurality of pixels PX. Each of the plurality of pixels PX may be configured by a plurality of sub pixels. A plurality of light emitting diodes may be disposed in each of the plurality of sub pixels. For example, when the display device 1000 is an inorganic light emitting display device, the light emitting diode may be a light emitting diode (LED), a micro light emitting diode (micro LED), or a mini light emitting diode (mini LED), but the exemplary embodiments of the present disclosure are not limited thereto.

The non-active area NA is an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the exemplary embodiments of the present disclosure are not limited thereto.

According to the present disclosure, the non-active area NA may include a first non-active area NA1, a bending area BA, and a second non-active area NA2. For example, the first non-active area NA1 may be an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD may be disposed therein. For example, the bending area BA is in a bent state and the other areas of the substrate 110 excluding the bending area BA may be in a flat state. In this case, as the bending area BA is bent, the second non-active area NA2 may be located on a rear surface of the active area AA, but the exemplary embodiments of the present disclosure are not limited thereto.

The active area AA of the substrate 110 or the display device 1000 may be configured with various shapes depending on a design of the display device 1000. For example, the active area may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE are disposed may be larger than a width of the bending area BA in which only a plurality of link lines LL is disposed. Further, a width of the active area AA in which the plurality of sub pixels are disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

Referring to FIG. 3, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the plurality of pixel driving circuits PD may be driving drives manufactured using a metal-oxide-silicon field effect transistor (MOSFET) manufacturing process on a semiconductor substrate, but the exemplary embodiments of the present disclosure are not limited thereto. The driving driver includes a plurality of pixel driving circuits PD and may drive a plurality of sub pixels.

Referring to FIG. 1 together, the flexible circuit board 400 and the printed circuit board 500 may be disposed below the display panel 100. The flexible circuit board 400 and the printed circuit board 500 may be disposed at least at one edge of the display panel 100, but the exemplary embodiments of the present disclosure are not limited thereto. One side of the flexible circuit board 400 is attached to the display panel 100 and the other side is attached to the printed circuit board 500, but the exemplary embodiments of the present disclosure are not limited thereto. The flexible circuit board 400 may be a flexible film, but the exemplary embodiments of the present disclosure are not limited thereto.

A pad unit PAD including a plurality of pad electrodes PE may be disposed in the second non-active area NA2. In the pad unit PAD, a driving component including one or more flexible circuit board (or a flexible film) 400 and the printed circuit board 500 may be attached or bonded. The plurality of pad electrodes PE of the pad unit PAD are electrically connected to one or more flexible circuit boards (or flexible films) 400 and may transmit various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the exemplary embodiments of the present disclosure are not limited thereto. The flexible circuit board (or flexible film) 400 may be attached or bonded onto the plurality of pad electrodes PE through a conductive adhesive layer, but the exemplary embodiments of the present disclosure are not limited thereto.

The printed circuit board 500 may be a component which is electrically connected to one or more flexible circuit boards (or flexible films) 400 and supplies a signal to the driving IC. The printed circuit board 500 is disposed at one side of the flexible circuit board (or flexible film) 400 to be electrically connected to the flexible circuit board (or flexible film) 400. On the printed circuit board 500, various components for supplying various signals to the driving IC may be disposed. For example, on the printed circuit board 500, various components, such as a timing controller, a power source, a memory, or a processor, may be disposed and may include a power management integrated circuit (PMIC), but the exemplary embodiments of the present disclosure are not limited thereto.

The printed circuit board 500 may include at least one hole 510, but the exemplary embodiments of the present disclosure are not limited thereto. An internal component which senses ambient light or temperature to be supplied to a plurality of sensors may be disposed in an area corresponding to at least one hole 510.

Referring to FIG. 1, a polarization layer 293 may be disposed on the display panel 100. The polarization layer 293 may suppress or reduce the influence on the micro LED caused by light generated from an external light source and entering the display panel 100.

A cover member 200 may be disposed on the polarization layer 293. The cover member 200 may be a member for protecting the display panel 100. An adhesive layer 295 may be disposed between the polarization layer 293 and the cover member 200. The cover member 200 may be attached to the display panel 100 using the adhesive layer 295. The adhesive layer 295 may include an optically clear adhesive (OCA), an optically clear resin (OCR), or a pressure sensitive adhesive (PSA), but the exemplary embodiments of the present disclosure are not limited thereto.

A support substrate 300 may be disposed between the display panel 100 and the printed circuit board 500. The support substrate 300 may reinforce a rigidity of the display panel 100. The support substrate 300 may be a back plate, but the exemplary embodiments of the present disclosure are not limited thereto.

Referring to FIGS. 1 to 3, the plurality of link lines LL may be disposed in the non-active area NA. The plurality of link lines LL may be wiring lines which transmit various signals from one or more flexible circuit boards (or flexible films) 400 and the printed circuit board 500 to the active area AA. The plurality of link lines LL extend from the plurality of pad electrodes PE of the second non-active area NA2 toward the bending area BA and the first non-active area NA1 to be electrically connected to the plurality of driving lines VL of the active area AA.

For example, the plurality of driving lines VL may be wiring lines for transmitting a signal output from the flexible circuit board (or flexible film) 400 and the printed circuit board 500 to the plurality of pixel driving circuits PD together with the plurality of link lines LL. The plurality of driving lines VL are disposed in the active area AA to be electrically connected to each of the plurality of pixel driving circuits PD. The plurality of driving lines VL extend toward the non-active area NA from the active area AA to be electrically connected to the plurality of link lines LL. Accordingly, a signal output from the flexible circuit board (or flexible film) 400 and the printed circuit board 500 may be transmitted to each of the plurality of pixel driving circuits PD through the plurality of link lines LL and the plurality of driving lines VL.

As the bending area BA is bent, a part of the plurality of link lines LL is bent together. A stress is concentrated in the bent part of the link line LL, which causes a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the exemplary embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the exemplary embodiments of the present disclosure are not limited thereto.

The plurality of link lines LL may be configured with various shapes to reduce a stress. At least a part of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least a part of the plurality of link lines LL may be configured by various shapes of patterns. For example, at least a part of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the exemplary embodiments of the present disclosure are not limited thereto.

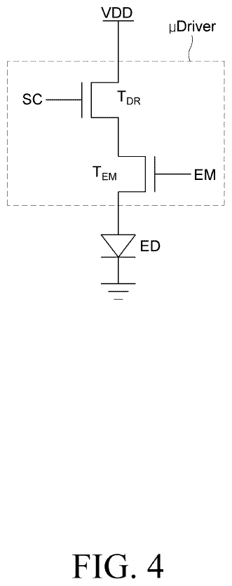

FIG. 4 is a view illustrating a circuit structure according to an exemplary embodiment of the present disclosure.

A pixel driving circuit PD may include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LED (ED) may be simultaneously connected to one micro driver (μDriver).

One micro driver (μDriver) may include a driving transistor TDR and an emission transistor TEM, but the exemplary embodiments of the present disclosure are not limited thereto.

For example, a high potential power voltage VDD is applied to a first electrode of the driving transistor TDR and a first electrode of the emission transistor TEM is connected to a second electrode, and a scan signal SC may be applied to a gate electrode. The scan signal SC applied to the gate electrode of the driving transistor TDR is a direct current (DC) power and a fixed reference voltage may be applied in every frame, but the exemplary embodiments of the present disclosure are not limited thereto.

The second electrode of the driving transistor TDR is connected to a first electrode of the emission transistor TEM, the micro LED (ED) is connected to a second electrode, and the emission signal EM may be applied to a gate electrode. The emission signal EM applied to the gate electrode of the emission transistor TEM may be a pulse width modulation signal which changes in every frame, but the exemplary embodiments of the present disclosure are not limited thereto.

A first electrode of the micro LED (ED) is connected to the second electrode of the emission transistor TEM and a second electrode may be connected to the ground. For example, the first electrode is an anode electrode and the second electrode may be a cathode electrode, but the exemplary embodiments of the present disclosure are not limited thereto.

The driving transistor TDR is turned on by a scan signal SC applied from the timing controller T-CON to the micro driver (μDriver) and the emission transistor TEM is turned on by the emission signal EM. By doing this, the driving current is applied to the micro LED (ED) via the driving transistor TDR and the emission transistor TEM by the high potential power voltage VDD applied to the first electrode of the driving transistor TDR so that the micro LED (ED) may emit light.

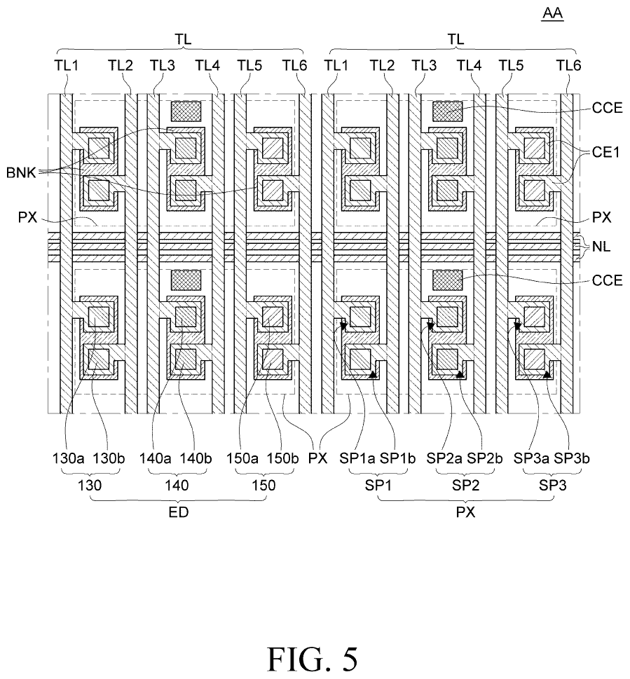

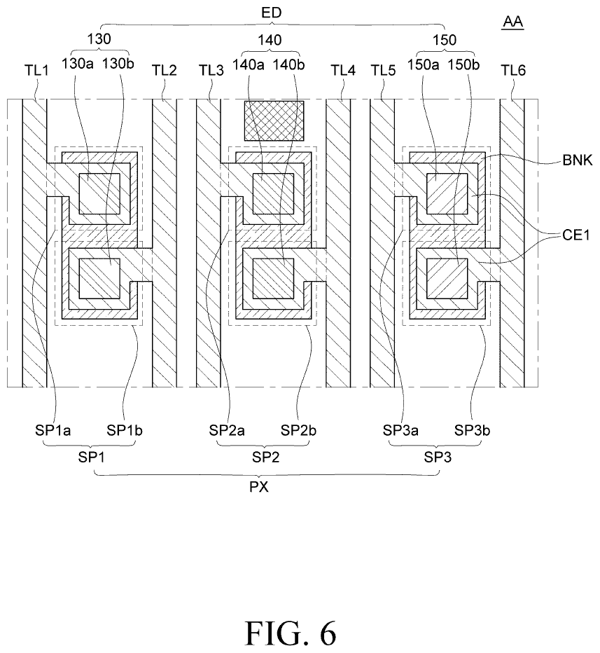

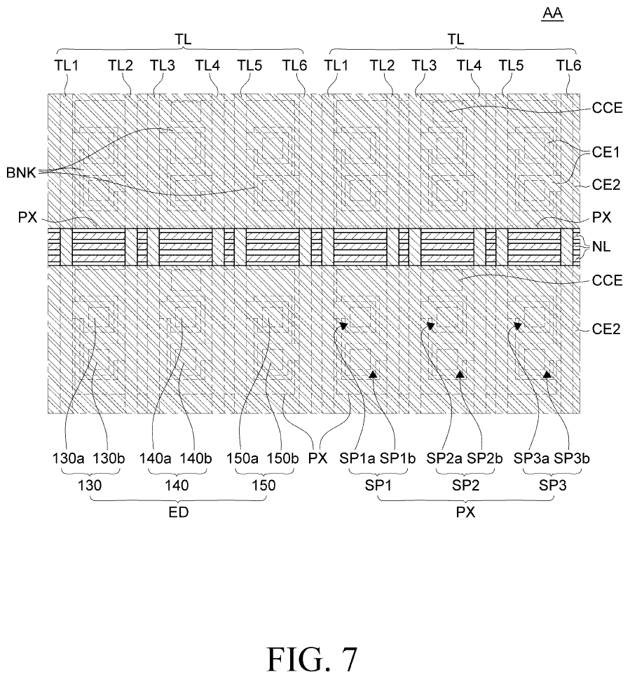

FIGS. 5 to 7 are plan views of a display device according to an exemplary embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, a plurality of signal lines TL, a plurality of communication lines NL, a plurality of first electrodes CE1, a plurality of banks BNK, and a plurality of micro LEDs (ED) are illustrated, but the exemplary embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which are configured by a plurality of sub pixels may be disposed in the active area AA. Each of the plurality of sub pixels includes a micro LED (ED) and may independently emit light. The plurality of sub pixels may be disposed in a matrix by forming a plurality of rows and a plurality of columns, but the exemplary embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 is a red sub pixel, another is a green sub pixel, and the third may be a blue sub pixel. The types of the plurality of sub pixels are illustrative, but the exemplary embodiments of the present disclosure are not limited thereto.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1-th sub pixel SP1a and a 1-2-th sub pixel SP1b. One pair of second sub pixels SP2 may be configured by a 2-1-th sub pixel SP2a and a 2-2-th sub pixel SP2b. One pair of third sub pixels SP3 may be configured by a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the exemplary embodiments of the present disclosure are not limited thereto.

The plurality of sub pixels which form one pixel PX may be disposed in various ways. For example, in one pixel PX, one pair of first sub pixels SP1 is disposed on the same column, one pair of second sub pixels SP2 is disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the exemplary embodiments of the present disclosure are not limited thereto.

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL.

Accordingly, instead of the plurality of transistors and storage capacitors formed in each of the plurality of sub pixels, a pixel driving circuit PD in which a plurality of pixel circuits are integrated is used to simplify the structure of the display device 1000. Further, a circuit which is disposed in each of the plurality of sub pixels is integrated in one pixel driving circuit PD so that highly efficient low power driving is possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 is disposed on one of one pair of first sub pixels SP1 and the second signal line TL2 may be disposed on the other one of one pair of first sub pixels SP1. The first signal line TL1 may be electrically connected to the first electrode CE1 of the 1-1-th sub pixel SP1a. The second signal line TL2 may be electrically connected to the first electrode CE1 of the 1-2-th sub pixel SP1b.

The third signal line TL3 is disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may be electrically connected to the first electrode CE of the 2-1-th sub pixel SP2a. The fourth signal line TL4 may be electrically connected to the first electrode CE1 of the 2-2-th sub pixel SP2b.

The fifth signal line TL5 is disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to the first electrode CE1 of the 3-1-th sub pixel SP3a. The sixth signal line TL6 may be electrically connected to the first electrode CE1 of the 3-2-th sub pixel SP3b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. The plurality of communication lines NL are disposed in the area between the plurality of second electrodes CE2 and does not overlap the plurality of second electrodes CE2. For example, the plurality of communication lines NL may be wiring lines used for short distance communication, such as near field communication (NFC). The plurality of communication lines NL may serve as antennas.

According to the present disclosure, a bank BNK may be disposed in each of the plurality of sub pixels. The plurality of banks BNK may be structures in which the plurality of micro LEDs (ED) are seated. The plurality of banks BNK may guide a position of the plurality of micro LEDs (ED) during a transfer process of transferring the plurality of micro LEDs (ED) to the display device 1000. The plurality of micro LEDs (ED) may be transferred onto the plurality of banks BNK in the transfer process of the plurality of micro LEDs (ED). The plurality of banks BNK may be a bank pattern or a structure, but the exemplary embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs (ED) are transferred may be easily identified.

The bank BNK of the 1-1-th sub pixel SP1a and the bank BNK of the 1-2-th sub pixel SP1b may be connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed may be connected to each other or spaced apart or separated from each other. Further, the bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of third sub pixels SP3 are formed in various forms, but the exemplary embodiments of the present disclosure are not limited thereto.

For example, the plurality of banks BNK may be formed of an organic insulating material. The plurality of banks BNK are configured by a single layer or a double layer of an organic insulating material. For example, the plurality of banks BNK is configured by a photo resist, polyimide (PI), or acrylic-based material, but the exemplary embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. Each of the first electrode CE1 of the 2-1-th sub pixel SP2a, the first electrode CE1 of the 2-2-th sub pixel SP2b, the first electrode CE1 of the 3-1-th sub pixel SP3a, and the first electrode CE1 of the 3-2-th sub pixel SP3b may be electrically connected to each of the nearest signal lines, i.e., the third signal line TL3, the fourth signal line TL4, the fifth signal line TL5, and the sixth signal line TL6.

The first electrode CE1 is electrically connected to the anode electrode 134 of the micro LED (ED) and may transmit an anode voltage from the pixel driving circuit PD to the micro LED (ED) through the signal line TL. Different voltages may be applied to the first electrodes CE1 of the plurality of sub pixels depending on the image to be displayed. Therefore, the first electrode CE1 may be a pixel electrode, but the exemplary embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same conductive material as the plurality of signal lines TL, but the exemplary embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the exemplary embodiments of the present disclosure are not limited thereto.

The micro LED (ED) may be disposed in each of the plurality of sub pixels. The plurality of micro LEDs (ED) may be disposed on the bank BNK and the first electrode CE1. The plurality of micro LEDs (ED) are disposed on the first electrode CE1 and is electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 is a red micro LED, another is a green micro LED, and the third is a blue micro LED, but the exemplary embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the exemplary embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 includes a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 may be disposed in each of the plurality of sub pixels. The second electrode CE2 may be disposed on the micro LED (ED). The second electrode CE2 may be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage may be applied to the second electrode CE2 of each of the plurality of sub pixels and the cathode electrode 135 of the micro LED (ED). Therefore, the second electrode CE2 may be a common electrode, but the exemplary embodiments of the present disclosure are not limited thereto.

At least some of the plurality of sub pixels may share the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes of at least some pixels PX, among the plurality of pixels PX disposed on the same row may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in a n-th row and a second electrode CE2 connected to pixels PX in a n+1-th row may be spaced apart or separated from each other. For example, the plurality of second electrodes CE2 may be disposed to be spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the exemplary embodiments of the present disclosure are not limited thereto.

The plurality of second electrodes CE2 may be configured by a transparent conductive material, but the exemplary embodiments of the present disclosure are not limited thereto. The plurality of second electrodes CE2 are configured by a transparent conductive material so that light emitted from the micro LED (ED) may travel toward the top of the second electrode CE2. For example, the second electrode CE2 may be configured by a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE are disposed between the substrate 110 and the plurality of second electrodes CE2 to transmit a cathode voltage from the pixel driving circuit PD to the second electrode CE2.

When the micro LED (ED) is used as a light emitting element, a plurality of micro LEDs are formed on a wafer and the micro LED is transferred onto the substrate 110 of the display device 1000 to manufacture the display device 1000. During the process of transferring the plurality of micro LEDs (ED) having a micro size from the wafer to the substrate 110, various defects may be caused. For example, in some sub pixel, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) may be defective. Accordingly, in consideration of the defects for the transfer process of the plurality of micro LEDs (ED), a plurality of same type micro LEDs may be transferred in one sub pixel. The lighting test for the plurality of micro LEDs (ED) is performed and only one micro LED (ED) which is finally determined to be normal may be used.

For example, the 1-1-th micro LED 130a and the 1-2-th micro LED 130b are transferred to one pixel PX together and defects thereof may be tested. If both the 1-1-th micro LED 130a and the 1-2-th micro LED 130b are determined to be normal, only the 1-1-th micro LED 130a is used, but the 1-2-th micro LED 130b is not used. As another example, if only the 1-2-th micro LED 130b between the 1-1-th micro LED 130a and the 1-2-th micro LED 130b is determined to be normal, the 1-1-th micro LED 130a is not used, but only the 1-2-th micro LED 130b may be used. Accordingly, even though the plurality of same type micro LEDs (ED) is transferred to one pixel PX, finally, only one micro LED (ED) may be used.

Therefore, any one of one pair of micro LEDs (ED) is a main (or primary) micro LED (ED) and the other micro LED (ED) may be a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized.

For example, a 1-1-th micro LED 130a, a 2-1-th micro LED 140a, and a 3-1-th micro LED 150a which are transferred to one pixel PX are used as main micro LEDs (ED) and a 1-2-th micro LED 130b, a 2-2-th micro LED 140b, and a 3-2-th micro LED 150b may be used as redundancy micro LEDs (ED).

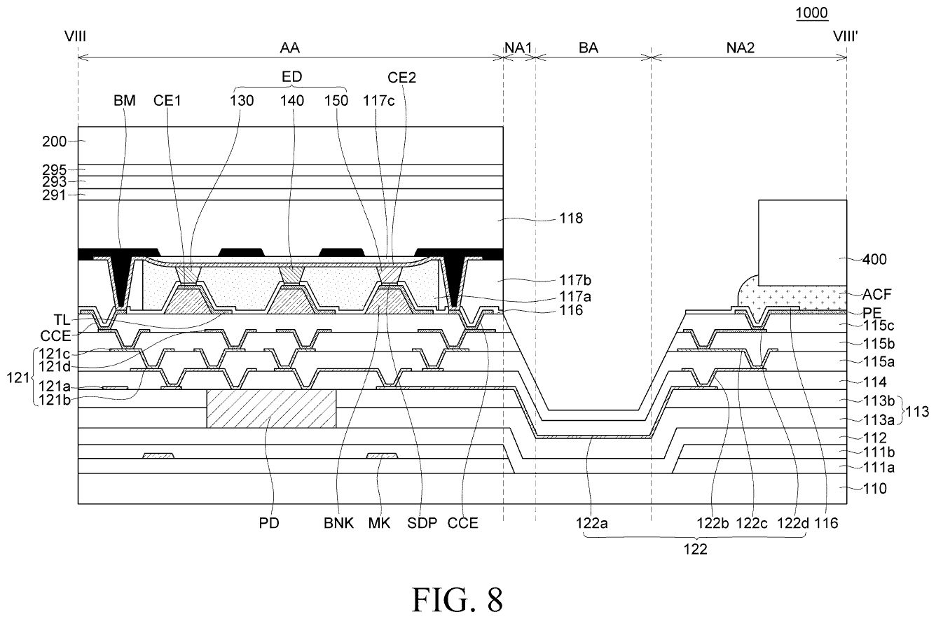

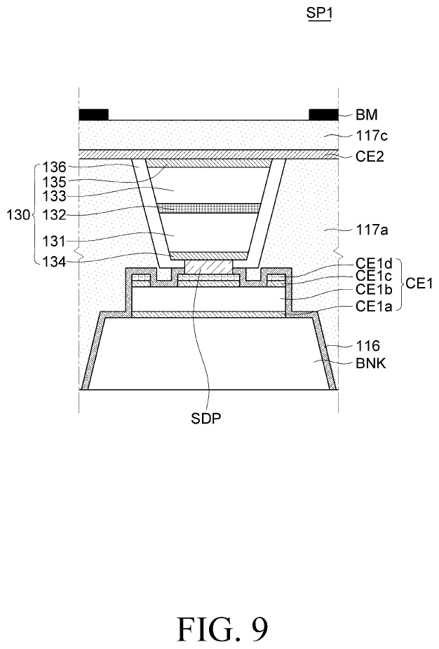

FIG. 8 is a cross-sectional view taken along VIII-VIII′ of FIG. 3 according to an exemplary embodiment of the present disclosure. FIG. 9 is a cross-sectional view of a display device according to an exemplary embodiment of the present disclosure. FIG. 8 is a cross-sectional view of a display device according to an exemplary embodiment of the present disclosure. For example, FIG. 8 is a cross-sectional view of an active area AA, a first non-active area NA1, a bending area BA, and a second non-active area NA2. For example, FIG. 9 is an enlarged cross-sectional view of a first sub pixel. In the meantime, for the convenience of illustration, in FIG. 3, it is illustrated that a cross-sectional line of VIII-VIII′ and a driving line VL and a link line LL do not overlap, but the cross-sectional line VIII-VIII′ of FIG. 3 is provided to represent the same position as the adjacent driving line VL and link line LL.

Referring to FIG. 8, when the pixel driving circuit PD is implemented as a driving driver, the driving driver may be mounted on the substrate 110 by the transfer process, but the exemplary embodiments of the present disclosure are not limited thereto. A first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2.

The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or a plurality of layers of silicon oxide (SiOx) or silicon nitride (SiNx), but the exemplary embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or at least reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the exemplary embodiments of the present disclosure are not limited thereto.

A protection layer 113 may be disposed on the adhesive layer 112 and the pixel driving circuit PD. The protection layer 113 may be disposed so as to enclose the pixel driving circuit PD, but the exemplary embodiments of the present disclosure are not limited thereto. For example, the protection layer 113 may be disposed so as to cover at least a part of a side surface of the pixel driving circuit PD. As another example, the protection layer 113 may be disposed so as to cover at least a part of a top surface of the pixel driving circuit PD.

The protection layer 113 may include one or more organic insulating layers. For example, the protection layer 113 may include a first protection layer 113a disposed on the adhesive layer 112 and a second protection layer 113b disposed on the first protection layer 113a. For example, the first protection layer 113a and the second protection layer 113b may be disposed so as to enclose a side surface of the pixel driving circuit PD. For example, the second protection layer 113b may be disposed so as to cover at least a part of a top surface of the pixel driving circuit PD. For example, at least one of the first protection layer 113a and the second protection layer 113b disposed on the bending area BA may be omitted. For example, the first protection layer 113a is entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed. However, the protection layer 113 may be formed by a single layer, but the exemplary embodiments of the present disclosure are not limited thereto.

The first protection layer 113a and the second protection layer 113b of the protection layer may be configured by an organic insulating material, but the exemplary embodiments of the present disclosure are not limited thereto. For example, the first protection layer 113a and the second protection layer 113b may be configured by a photo resist, polyimide (PI), or photo acrylic-based material, but the exemplary embodiments of the present disclosure are not limited thereto. For example, the first protection layer 113a and the second protection layer 113b may be an over coating layer or an insulating layer, but the exemplary embodiments of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121d, but the exemplary embodiments of the present disclosure are not limited thereto.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CEL or the second electrode CE2.

For example, an additional protection layer may be further disposed on the second protection layer 113b. For example, a third protection layer 114 may be further disposed on the second protection layer 113b. The third planarization layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic-based material, but the exemplary embodiments of the present disclosure are not limited thereto. For example, the first protection layer 113a, the second protection layer 113b, and the third protection layer 114 may be configured by the same material, but the exemplary embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114. However, the exemplary embodiments of the present disclosure are not limited thereto. A voltage output from the pixel driving circuit PD may be transmitted to the first electrode CE1 or the second electrode CE2 through a connection line other than the plurality of 1-2-th connection lines 121b.

The first insulating layer 115a may be disposed on the plurality of 1-2-th connection lines 121b. The first insulating layer 115a may be entirely disposed in the active area AA and the non-active area NA, but the exemplary embodiments of the present disclosure are not limited thereto. The first insulating layer 115a may be configured by an organic insulating material, but the exemplary embodiments of the present disclosure are not limited thereto. For example, the first insulating layer 115a may be configured by a photo resist, polyimide (PI), or photo acrylic-based material, but the exemplary embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b may be configured by an organic insulating material, but the exemplary embodiments of the present disclosure are not limited thereto. For example, the second insulating layer 115b is configured by a photo resist, polyimide (PI), or photo acrylic-based material, but the exemplary embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) 400 and the printed circuit board 500 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500. Further, the plurality of second connection lines 122 directly transmits a signal to the pixel driving circuit PD or transmits signal to the pixel driving circuit PD through the first connection line 121. Further, the pixel driving circuit PD may output a cathode voltage to the plurality of contact electrodes CCE and the plurality of sub pixels based on a signal applied from the second connection line 122.

For example, the plurality of second connection lines 122 extends toward the active area AA from the pad unit PAD to transmit a signal to the pixel driving circuit PD of the active area AA. In this case, the plurality of second connection lines 122 may serve as a link line LL. The plurality of second connection lines 122 may include a 2-1-th connection lines 122a, a 2-2-th connection lines 122b, a 2-3-th connection lines 122c, and a 2-4-th connection lines 122d.

The plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) 400 and the printed circuit board 500 to the pad unit PAD to the pixel driving circuit PD of the active area AA. For example, a 2-1-th connection line 122a extends from the second non-active area NA2 to the first non-active area NA1 and may be directly electrically connected to the pixel driving circuit PD or may be electrically connected to the pixel driving circuit PD through the plurality of first connection lines 121.

The plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through the contact hole of the third protection layer 114. Accordingly, a signal from the flexible circuit board (or flexible film) 400 and the printed circuit board 500 may be transmitted to the 2-1-th connection line 122a through the 2-2-th connection line 122b.

The 2-3-th connection lines 122c may be disposed on the first insulating layer 115a. The 2-3-th connection lines 122c may be disposed in the second non-active area NA2. The 2-3-th connection lines 122c may be electrically connected to the 2-2-th connection line 122b through a contact hole of the first insulating layer 115a. Accordingly, a signal from the flexible circuit board (or flexible film) 400 and the printed circuit board 500 may be transmitted to the 2-1-th connection line 122a through the 2-3-th connection line 122c and the 2-2-th connection line 122b.

The 2-4-th connection lines 122d may be disposed on the second insulating layer 115b. The 2-4-th connection lines 122d may be disposed in the second non-active area NA2. The 2-4-th connection lines 122d may be electrically connected to the 2-3-th connection line 122c through a contact hole of the second insulating layer 115b. Accordingly, a signal from the flexible circuit board (or flexible film) 400 and the printed circuit board 500 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the exemplary embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may be configured by an organic insulating material, but the exemplary embodiments of the present disclosure are not limited thereto. For example, the third insulating layer 115c may be configured by a photo resist, polyimide (PI), or photo acrylic-based material, but the exemplary embodiments of the present disclosure are not limited thereto.

A plurality of banks BNK may be disposed on the third insulating layer 115c in the active area AA. The plurality of banks BNK may be disposed so as to overlap each of the plurality of sub pixels. One or more same type micro LED (ED) may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 9, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the exemplary embodiments of the present disclosure are not limited thereto.

According to the present disclosure, some conductive layer having a good reflection efficiency, among a plurality of conductive layers which configures the first electrode CE1 may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1 has a high reflection efficiency to be easily identified during the manufacturing process so that a position of the micro LED (ED) or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remains and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SPD, and has corrosion resistance and acid resistance. However, the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the exemplary embodiments of the present disclosure are not limited thereto.

According to the present disclosure, the signal line TL, the contact electrode CCE, and the pad electrode PE disposed on the same layer as the first electrode CE1 may be configured by a plurality of layers of conductive materials, but the exemplary embodiment of the present disclosure are not limited thereto. For example, the signal line TL, the contact electrode CCE, and the pad electrode PE may be formed of a plurality of layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, a solder pattern SDP may be disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) may be electrically connected through eutectic bonding using the solder pattern SDP, but the exemplary embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) may be bonded to the solder pattern SDP and the first electrode CE1 using the eutectic bonding without a separate adhesive material. For example, the solder pattern SDP may be configured by indium (Id), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto.

According to the present disclosure, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may be configured by a single layer or a plurality of layers of silicon oxide (SiOx) or silicon nitride (SiNx), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole through which the solder pattern SDP is exposed.

In each of the plurality of sub pixels, the micro LED (ED) may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED (ED) may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 9, the first micro LED 130 may include an anode electrode 134, a first semiconductor layer 131, an active layer 132, a second semiconductor layer 133, a cathode electrode 135, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 is an n-type impurity doped semiconductor layer and the other one is a p-type impurity doped semiconductor, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Se), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each the first semiconductor layer 131 and the second semiconductor layer 133 may be a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by one of a single well structure, a multi-well structure, a signal quantum well structure, a multi-quantum well (MQC) structure, a quantum dot structure, and a quantum line structure, but the exemplary embodiments of the present disclosure are not limited thereto. For example, the active layer 132 may be configured by indium gallium nitride (InGaN) or gallium nitride (GaN), but the exemplary embodiments of the present disclosure are not limited thereto.

As another example, the active layer 132 has a multi quantum well (MQW) structure having a well layer and a barrier layer with a band gap higher than the well layer. For example, in the active layer 132, InGaN is configured as a well layer and an AlGaN layer is configured as a barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the exemplary embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the exemplary embodiments of the present disclosure are not limited thereto. For example, the cathode electrode 135 may be configured by a material, such as indium tin oxide (ITO), indium zinc oxide (IZO), indium gallium zinc oxide (IGZO), but the exemplary embodiments of the present disclosure are not limited thereto.

The encapsulation film 136 may be disposed in at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the exemplary embodiments of the present disclosure are not limited thereto.

As another example, the encapsulation film 136 may have a structure in which a reflective material is dispersed in a resin layer, but the exemplary embodiments of the present disclosure are not limited thereto. For example, the encapsulation film 136 may be manufactured with reflectors with various structures, but the exemplary embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the exemplary embodiments of the present disclosure are not limited thereto.

According to the present disclosure, it is described that the micro LED (ED) has a vertical structure, that is, a vertical type micro LED, but the exemplary embodiments of the present disclosure are not limited thereto. For example, the micro LED (ED) may have a lateral structure or a flip-chip structure.

The first micro LED 130 has been described with reference to FIG. 9 and the second micro LED 140 and the third micro LED 150 may have the substantially same structure as the first micro LED 130.

According to the present disclosure, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a row direction and may be spaced apart from each other in a column direction. For example, the first optical layer 117a may be disposed so as to enclose side portions of the micro LED (ED) and the bank BNK between the passivation layer 116 and the second electrode CE2, but the exemplary embodiments of the present disclosure are not limited thereto. For example, the first optical layer 117a may be a diffusion layer or a side wall diffusion layer, but the exemplary embodiments of the present disclosure are not limited thereto.

The first optical layer 117a may include an organic insulating material in which micro particles are dispersed, but the exemplary embodiments of the present disclosure are not limited thereto. For example, the first optical layer 117a may be configured by siloxane in which micro metal particles, such as titanium dioxide (TiO2) particles, are dispersed, but the exemplary embodiments of the present disclosure are not limited thereto. Light from the plurality of micro LEDs (ED) is scattered by micro particles dispersed in the first optical layer 117a to be emitted to the outside of the display device 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the exemplary embodiments of the present disclosure are not limited thereto. For example, the first optical layer 117a is disposed in each of the plurality of pixels PX or the plurality of pixels PX may share one first optical layer 117a. As another example, each of the plurality of sub pixels separately includes the first optical layer 117a, but the exemplary embodiments of the present disclosure are not limited thereto.

According to the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the exemplary embodiments of the present disclosure are not limited thereto. For example, the second optical layer 117b may be a diffusion layer, a diffusion window, or a window diffusion layer, but the exemplary embodiments of the present disclosure are not limited thereto.

The second optical layer 117b may be configured by an organic insulating material, but the exemplary embodiments of the present disclosure are not limited thereto. The second optical layer 117b may be configured by the same material as the first optical layer 117a, but the exemplary embodiments of the present disclosure are not limited thereto. For example, the first optical layer 117a may include micro particles, but the second optical layer 117b does not include micro particles. For example, the second optical layer 117b is configured by siloxane, but the exemplary embodiments of the present disclosure are not limited thereto.

For example, a thickness of the first optical layer 117a may be smaller than a thickness of the second optical layer 117b, but the exemplary embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the exemplary embodiments of the present disclosure are not limited thereto. For example, the second electrode CE2 may be disposed to be in contact with the cathode electrode 135. For example, the second electrode CE2 may overlap the first optical layer 117a. For example, the second electrode may cover a plane at the outside of the first optical layer 117a.

The second electrode CE2 may continuously extend in a first direction of the substrate 110. Accordingly, the second electrode may be commonly connected to the plurality of pixels PX disposed in the first direction of the substrate 110. For example, the second electrode CE2 may be commonly connected to the plurality of pixels PX.

According to the present disclosure, the second electrode CE2 may continuously extend on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be improved. For example, when the plurality of micro LEDs (ED) is transferred onto the substrate 110 of the display device 1000, an area in which the interval between the plurality of micro LEDs (ED) is not uniform may be caused due to the process deviation. When the interval between the plurality of micro LEDs (ED) is not uniform, an emission area of each of the plurality of micro LEDs (ED) is not uniformly disposed so that the mura may be visible to a user. Accordingly, the third optical layer 117c which is configured to uniformly diffuse light is configured above the plurality of micro LEDs (ED) so that light emitted from some micro LED (ED) which is visible as mura may be reduced. Accordingly, light emitted from the plurality of micro LEDs (ED) is uniformly diffused by the third optical layer 117c to be extracted to the outside of the display device 1000 so that the luminance uniformity of the display device 1000 may be improved.

The third optical layer 117c may be configured by an organic insulating material in which micro particles are dispersed, but the exemplary embodiments of the present disclosure are not limited thereto. For example, the third optical layer 117c may be configured by siloxane in which micro metal particles, such as titanium dioxide (TiO2) particles, are dispersed, but the exemplary embodiments of the present disclosure are not limited thereto. For example, the third optical layer 117c is configured by the same material as the first optical layer 117a, but the exemplary embodiments of the present disclosure are not limited thereto. For example, the third optical layer 117c may be a diffusion layer or a upward diffusion layer, but the exemplary embodiments of the present disclosure are not limited thereto.

According to the present disclosure, light from the plurality of micro LEDs (ED) is scattered by micro particles dispersed in the third optical layer 117c to be emitted to the outside of the display device 1000. The third optical layer 117c uniformly mixes light emitted from the plurality of micro LEDs (ED) to further improve the luminance uniformity of the display device 1000. Further, the light extraction efficiency of the display device 1000 may be improved by light scattered from the plurality of micro particles so that the display device 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the exemplary embodiments of the present disclosure are not limited thereto. For example, the black matrix BM may be configured by an organic insulating material to which black pigment or black dye are added, but the exemplary embodiments of the present disclosure are not limited thereto.

In the active area AA, a cover layer 118 may be disposed on the black matrix BM. The cover layer 118 may protect configurations below the cover layer 118. For example, the cover layer 118 may be configured by an organic insulating material, but the exemplary embodiments of the present disclosure are not limited thereto. For example, the cover layer 118 may be configured by a photo resist, polyimide (PI), or photo acrylic-based material, but the exemplary embodiments of the present disclosure are not limited thereto. For example, the cover layer 118 may be an over coating layer or an insulating layer, but the exemplary embodiments of the present disclosure are not limited thereto.

A polarization layer 293 may be disposed on the cover layer 118 by means of the first adhesive layer 291. A cover member 200 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present disclosure, a plurality of pad electrodes PE may be disposed on the third insulating layer 115c in the second non-active area NA2. For example, at least a part of the plurality of pad electrodes PE may be exposed from the passivation layer 116. For example, the plurality of pad electrodes PE may be electrically connected to the 2-4-th connection line 122d and other connection lines through a contact hole of the third insulating layer 115c.

The adhesive layer ACF may be disposed on the plurality of pad electrodes PE. The adhesive layer ACF may be an adhesive layer in which conductive balls are dispersed in an insulating material, but the exemplary embodiments of the present disclosure are not limited thereto. When heat or a pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) 400, the flexible circuit board (or flexible film) 400 may be attached or bonded to the plurality of pad electrodes PE. For example, the adhesive layer ACF may be anisotropic conductive film, but the exemplary embodiments of the present disclosure are not limited thereto.

The flexible circuit board (or flexible film) 400 may be disposed on the adhesive layer ACF. The flexible circuit board (or flexible film) 400 may be electrically connected to the plurality of pad electrodes PE through the adhesive layer ACF. Accordingly, a signal output from the flexible circuit board (or flexible film) 400 and the printed circuit board 500 may be transmitted to the pixel driving circuit PD of the active area AA through the plurality of pad electrodes PE and the second connection line 122.

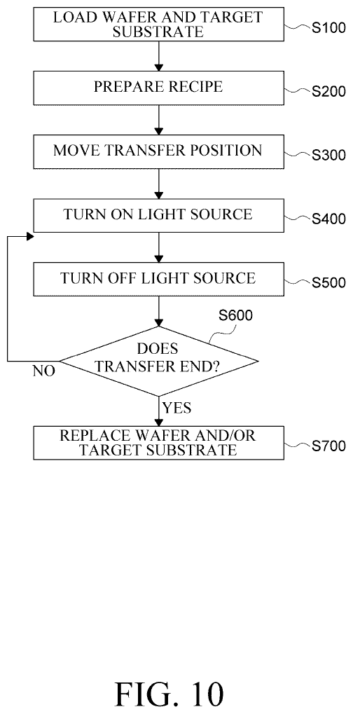

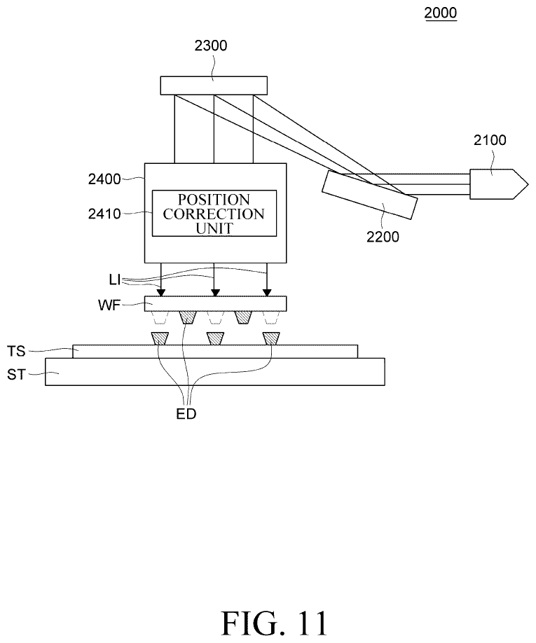

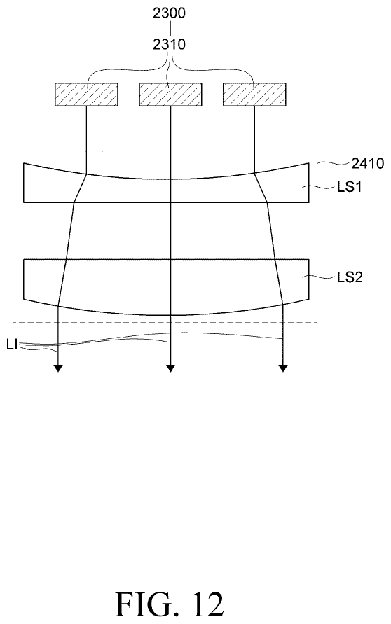

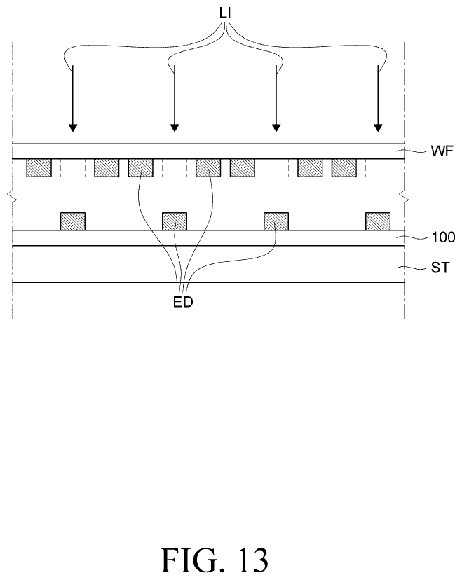

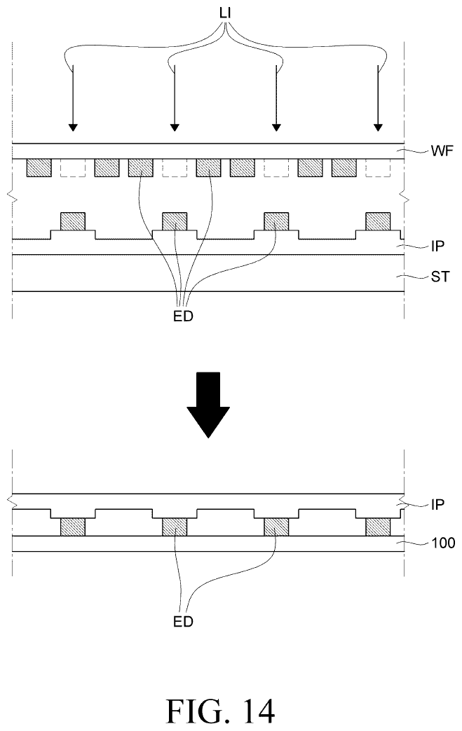

FIG. 10 is a process flowchart for explaining a fabricating method of a display device according to an exemplary embodiment of the present disclosure. FIG. 11 is a diagram illustrating a transfer device according to an exemplary embodiment of the present disclosure. FIG. 12 is a schematic cross-sectional view of an optical system of a transfer device according to an exemplary embodiment of the present disclosure. FIGS. 13 and 14 are cross-sectional views for explaining a fabricating method of a display device according to an exemplary embodiment of the present disclosure. Specifically, FIG. 13 is a cross-sectional view explaining a transfer process of a plurality of micro LEDs (ED) when a target substrate TS is a display panel 100 and FIG. 14 is a cross-sectional view explaining a transfer process of a plurality of micro LEDs (ED) when a target substrate TS is an interposer substrate IP.

Referring to FIGS. 10 and 11, the display device 1000 according to the exemplary embodiment of the present disclosure may be fabricated using a transfer device 200 configured to transfer a plurality of micro LEDs (ED) on a wafer WF onto the target substrate TS. For example, the plurality of micro LEDs (ED) are separated from the wafer WF using the transfer device 2000 and is transferred onto the display panel 100, to fabricate the display device 1000.

Referring to FIG. 11, the transfer device 2000 for transferring the plurality of micro LEDs (ED) may include a light source 2100, a reflective mirror 2200, a digital mirror device 2300, an optical system 2400, and a stage ST.

The light source 2100 may supply light LI to separate the plurality of micro LEDs (ED) from the wafer WF. The light LI from the light source 2100 may be irradiated onto the wafer WF via the reflective mirror 2200, the digital mirror device 2300, and the optical system 2400. The light source 2100 may be formed of an irradiation lamp, such as semiconductor laser, Halogen, Xenon, or Deuterium, but is not limited thereto.

The reflective mirror 2200 may reflect light LI from the light source 2100 to the digital mirror device 2300. Therefore, a path of the light LI emitted from the light source 2100 may be directed to the digital mirror device 2300 by the reflective mirror 2200.

The digital mirror device (DMD) 2300 includes a plurality of micro mirrors 2310 which sends incident light LI at a desired angle. The plurality of micro mirrors 2310 may be configured to be independently rotatable. Light LI of the light source 2100 may travel to various positions by individually controlling the angles of the plurality of micro mirrors 2310. The plurality of micro mirrors 2310 may be configured to be in any one of an on-state and an off-state by adjusting the angle of each of the plurality of micro mirrors 2310. For example, when the plurality of micro mirrors 2310 are in an on-state, the micro mirror 2310 may be disposed at an angle to reflect light LI from the light source 2100 and the reflective mirror 2200 toward the optical system 2400 and the wafer WF. For example, when the plurality of micro mirrors 2310 are in an off-state, the micro mirror 2310 may be disposed at an angle to reflect light LI from the light source 2100 and the reflective mirror 2200 toward a place other than the optical system 2400 and the wafer WF. The digital mirror device 2300 may be formed using a micro-electro mechanical system (MEMS) technique, but is not limited thereto.

Each of the plurality of micro mirrors 2310 may be driven so as to correspond to each of the plurality of micro LEDs (ED). For example, light LI reflected from one of the plurality of micro mirrors 2310 may be irradiated onto one micro LED (ED). At this time, when at least some of the plurality of micro LEDs (ED) are selectively transferred, only some of the plurality of micro mirrors 2310 may be driven in an on-state. Further, when a defect of some micro LED (ED) is confirmed, a micro mirror 2310 corresponding to the defective micro LED (ED) is controlled to be an off-state so as not to transfer the defective micro LED (ED). Therefore, whether to transfer the plurality of micro LEDs (ED) on the wafer WF is individually controlled using the digital mirror device 2300 having the plurality of micro mirrors 2310.

The optical system 2400 is a configuration which corrects light LI reflected from the plurality of micro mirrors 2310 of the digital mirror device 2300 to be irradiated onto the wafer WF and may include various optical devices. For example, the optical system 2400 may include a position correction unit 2410 (e.g., a position correction device) configured to correct a position of the plurality of light LI emitted from the plurality of micro mirrors 2310. For example, the position correction unit 2410 may adjust a position of light LI reflected from the plurality of micro mirrors 2310 to be incident into each of the plurality of micro LEDs (ED) of the wafer WF. For example, the position correction unit 2410 adjusts the position by adjusting a diameter, an interval, and an overall irradiation area of the plurality of light LI to allow the plurality of light LI to be incident to each of the plurality of micro LEDs (ED). The position correction unit 2410 may include optical devices to adjust a position of light LI, for example, various shapes of lenses, so that it may be defined as a lens unit.

Referring to FIG. 12, the position correction unit 2410 includes various optical elements to adjust the irradiation area of the plurality of light LI which is finally incident onto the wafer WF and a position of each of the plurality of light LI. For example, when a size of the digital mirror device 2300 is smaller than a size of the wafer WF, the irradiation area of the plurality of light LI emitted from the digital mirror device 2300 may be smaller than the wafer WF. Further, the interval between the plurality of light LI does not match the interval between the plurality of micro LEDs (ED). Therefore, the irradiation area of the plurality of light LI emitted from the digital mirror device 2300 may be enlarged using the position correction unit 2410 to correspond to at least a part of an area of the wafer WF. For example, the position correction unit 2410 may include a first lens LS1 and a second lens LS2. The position correction unit 2410 including the first lens LS1 and the second lens LS2 may entirely expand the plurality of light LI and may be defined as a beam expander. That is, the position correction unit 2410 may include a beam expander including a first lens LS1 and a second lens LS2. For example, the position correction unit 2410 expands a diameter of each of the plurality of light LI which is incident from the plurality of micro mirrors 2310 to the position correction unit 2410 and an interval between the plurality of light LI to expand the entire irradiation area of the plurality of light LI. Further, as the position correction unit 2410 expands the interval of the plurality of light LI so as to correspond to the interval of the plurality of micro LEDs (ED), the plurality of light LI may be incident onto the wafer WF so as to correspond to the position of each of the plurality of micro LEDs (ED). Accordingly, the position correction unit 2410 expands a range of irradiating light LI emitted from the digital mirror device 2300 to the entire wafer WF to adjust a coordinate of the plurality of light LI so as to be incident onto each of the plurality of micro LEDs (ED).

For example, the position correction unit 2410 includes a first lens LS1 configured with a concave top surface and a flat bottom surface and a second lens LS2 configured with a flat top surface and a convex bottom surface to expand the light LI reflected from the digital mirror device 2300. However, the configuration of the position correction unit 2410 is not limited thereto.

Further, even though it is not illustrated in the drawing, the position correction unit 2410 may further include a projection lens. For example, the projection lens may adjust a resolution of light LI outputted from the digital mirror device 2300 and the position correction unit 2410.

Next, referring to FIGS. 10 and 11, the transfer process may be performed in the order of a step S100 of loading a wafer WF and a target substrate TS, a step S200 of preparing a recipe, a step S300 of moving the wafer WF to a transfer position, a step S400 of controlling the light source 2100 to be an on-state, a step S500 of controlling the light source 2100 and the digital mirror device 2300 to be an off-state, a step S600 of determining the end of transfer, and a step S700 of replacing the wafer WF and/or the target substrate TS.

First, the wafer WF and the target substrate TS need to be loaded (S100). The wafer WF on which the plurality of micro LEDs (ED) is formed and the target substrate TS may be conveyed to a process position. For example, the target substrate TS is located on the stage ST and the wafer WF may be located above the target substrate TS.

The target substrate TS is a substrate to which the plurality of micro LEDs (ED) is transferred and may be a display panel 100 or an interposer substrate IP.

For example, referring to FIG. 13, if the target substrate TS is the display panel 100, the plurality of micro LEDs (ED) may be directly transferred onto the display panel 100 from the wafer WF. At this time, the display panel 100 may be in a state in which components up to the first electrode CE1 are formed on the bank BNK. Therefore, the plurality of micro LEDs (ED) may be directly transferred onto the first electrode CE1 on the bank BNK of the display panel 100 using the transfer device 2000.

For example, referring to FIG. 14, if the target substrate TS is an interposer substrate IP, a primary transfer process of the plurality of micro LEDs (ED) from the wafer WF to the interpose substrate IP is performed and a secondary transfer process of the plurality of micro LEDs (ED) from the interposer substrate IP to the display panel 100 may be performed. Further, the secondary transfer process from the interposer substrate IP to another interpose substrate IP may also be performed, but is not limited thereto.

In the meantime, the plurality of micro LEDs (ED) on the wafer WF may have a vertical structure as illustrated in FIGS. 8 and 9, or may be a lateral structure or a flip chip structure and the structure of the plurality of micro LEDs (ED) is not limited thereto. In this case, in consideration of a structure of the plurality of micro LEDs (ED) and an electrode placement direction of the micro LEDs (ED), the plurality of micro LEDs (ED) may be directly transferred from the wafer WF to the display panel 100 or the plurality of micro LEDs (ED) may be transferred from the wafer WF to the interposer substrate IP. Therefore, any one of the display panel 100 and the interposer substrate IP may be used as the target substrate TS in consideration of a structure of the plurality of micro LEDs (ED) and a structure of the display panel 100.

Next, a recipe is prepared (S200). The recipe may include process information required to perform the transfer process. The recipe may include process information, such as a driving condition of the transfer device 2000, for example, an output of the light source 2100 and an arrangement of the plurality of micro mirrors 2310 of the digital mirror device 2300. The recipe may vary depending on a process apparatus, and disclosures of the wafer WF, the target substrate TS, and the micro LED (ED).

Next, the wafer WF moves to the transfer position (S300). Specifically, a size of the wafer WF may be smaller than a size of the target substrate TS and in the single transfer process, the plurality of micro LEDs (ED) may be transferred to only a partial area of the target substrate TS. In this case, the target substrate TS is divided into a plurality of areas and the wafer WF moves so as to correspond to one area of the plurality of areas to perform the single transfer process. Further, the transfer process is performed in all the plurality of areas to transfer the plurality of micro LEDs (ED) onto the entire target substrate TS. Accordingly, the wafer WF may be located above an area of the plurality of areas of the target substrate TS where the transfer process will be performed.

At this time, a plurality of wafers WF, optical systems 2400, and digital mirror devices 2300 are disposed on one target substrate TS to perform the transfer process of the micro LEDs (ED) to the plurality of areas of the target substrate TS simultaneously. For example, when the target substrate TS is divided into n areas and one wafer WF, one optical system 2400, and one digital mirror device 2300 are disposed on the target substrate TS, the transfer process is performed n times to complete the transfer process of the plurality of micro LEDs (ED). For example, when the target substrate TS is divided into n areas and a plurality of wafers WF, optical systems 2400, and digital mirror devices 2300 are disposed on the target substrate TS and driven simultaneously, the transfer process is performed a number of times, smaller than n times, to complete the transfer process of the plurality of micro LEDs (ED). Accordingly, the plurality of optical systems 2400, and digital mirror devices 2300 of the transfer device 2000 are provided to shorten the process time.

Next, referring to FIGS. 10 and 11, the light source 2100 of the transfer device 2000 is controlled to be an on-state (S400). The light source 2100 of the transfer device 2000 is driven to separate the micro LED (ED) from the wafer WF by a laser lift off (LLO) method. For example, the light LI output from the light source 2100 may be irradiated onto the wafer WF via the reflective mirror 2200, the digital mirror device 2300, and the optical system 2400. Further, when the light LI is irradiated onto the wafer WF, light absorption occurs at the interface of the wafer WF and the semiconductor layers of the plurality of micro LEDs (ED) and the plurality of micro LEDs (ED) may be separated from the wafer WF due to a decomposition reaction of the semiconductor layers of the plurality of micro LEDs (ED). At this time, a separate sacrificial layer may be further formed between the wafer WF and the micro LED (ED) according to the configuration of the micro LED (ED), but is not limited thereto. Accordingly, light LI is selectively irradiated onto a micro LED (ED) to be transferred, among the plurality of micro LEDs (ED) to transfer the micro LED (ED) from the wafer WF to the target substrate TS.

At this time, the plurality of micro LEDs (ED) may be transferred onto the target substrate TS in a contactless manner. The light is irradiated to separate the plurality of micro LEDs (ED) from the wafer WT to be transferred onto the target substrate TS so that the influence of the flatness of the wafer WF and the target substrate TS during the transferring may be minimized or at least reduced. Accordingly, the plurality of micro LEDs (ED) is transferred in a contactless manner so that the process error according to the flatness of the wafer WF and the target substrate TS may be minimized or at least reduced.

Further, the light LI is simultaneously irradiated to the plurality of micro LEDs (ED) to perform the transfer process so that the time of the transfer process may be shortened. For example, the light LI may be simultaneously irradiated to the plurality of micro LEDs (ED) using the digital mirror device 2300 including a plurality of micro mirrors 2310 and the simultaneous transfer of the plurality of micro LEDs (ED) is possible so that the time for the transfer process may be shortened. The plurality of micro LEDs (ED) may be transferred in a large area in accordance with the resolution level of the digital mirror device 2300. Further, an angle of each of the plurality of micro mirrors 2310 is precisely controlled so that the plurality of light LI is more accurately irradiated onto the plurality of micro LEDs (ED) and a transfer precision of the plurality of micro LEDs (ED) may be improved.

Next, when the transfer process is primarily completed, the light source 2100 is controlled to be an off-state (S500). Next, whether the transfer ends may be determined (S600).

For example, when it is determined that the transfer process is not performed on all the plurality of areas of the target substrate TS, a step of moving the wafer WF to the transfer position may be performed. For example, when a transfer process on one area, among the plurality of areas of the target substrate TS, is completed, the wafer WF moves onto another area on which the transfer process is not performed, and then the light source 2100 and the digital mirror device 2300 are driven to perform the transfer process. Accordingly, the transfer process on the plurality of areas of the target substrate TS is repeatedly performed to transfer the plurality of micro LEDs (ED) onto the entire target substrate TS.

Next, after determining that the transfer is completed, the wafer WF and/or the target substrate TS is replaced (S700). For example, when all the plurality of micro LEDs (ED) on the wafer WF is transferred so that it is necessary to replace the wafer with another wafer WF or the transfer process is completed for the entire target substrate TS, the transfer process may end. Further, the wafer WF and/or the target substrate TS is replaced to perform a new transfer process.

Accordingly, the transfer device 2000 according to the exemplary embodiment of the present disclosure includes the digital mirror device 2300 to simultaneously transfer the plurality of micro LEDs (ED) so that the process time may be shortened. For example, the light LI may be simultaneously irradiated onto the plurality of micro LEDs (ED) using the digital mirror device 2300 including a plurality of micro mirrors 2310. Accordingly, the plurality of micro LEDs (ED) may be transferred onto the target substrate TS at one time, the process time is shortened, and the fabricating cost may be saved.

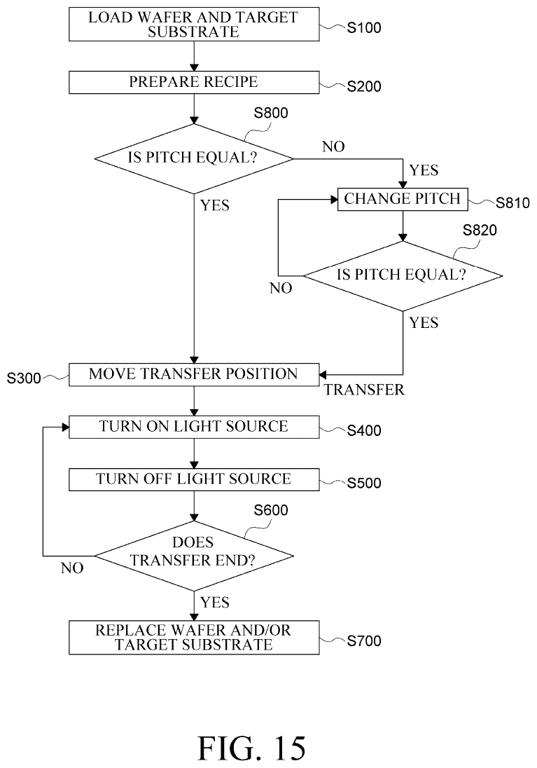

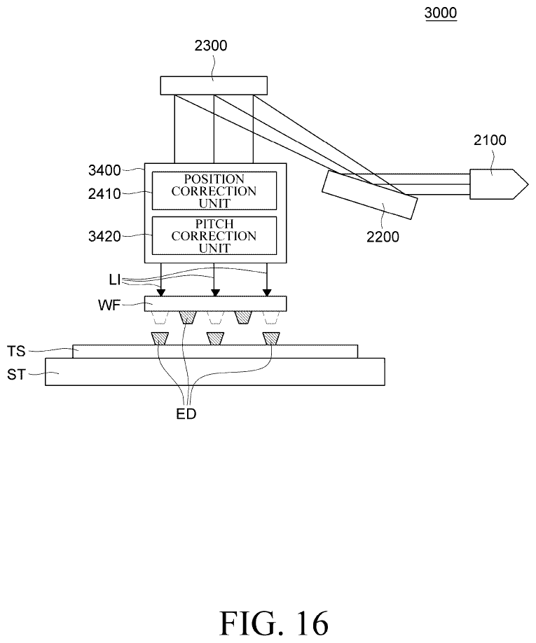

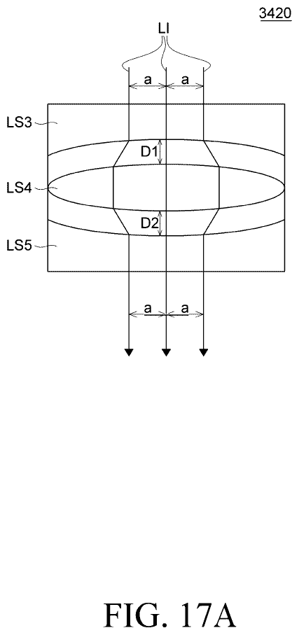

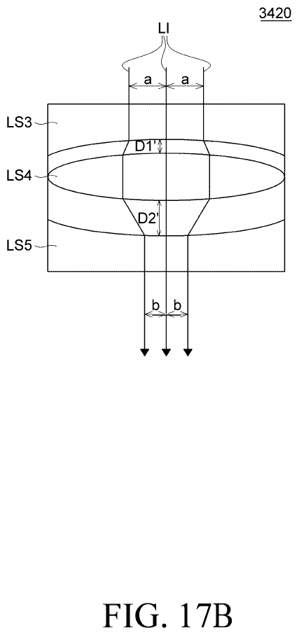

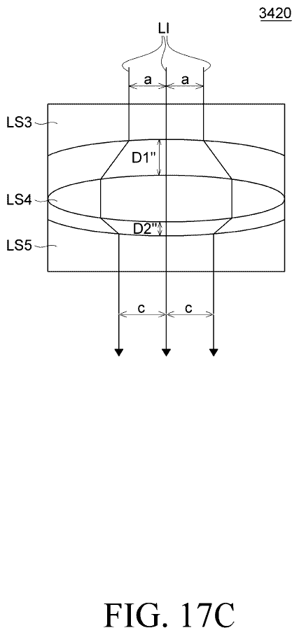

FIG. 15 is a process flowchart for explaining a fabricating method of a display device according to another exemplary embodiment of the present disclosure. FIG. 16 is a diagram illustrating a transfer device according to another exemplary embodiment of the present disclosure. FIGS. 17A to 17C are diagrams of a pitch correction unit of a transfer device according to another exemplary embodiment of the present disclosure. A transfer device 3000 of FIGS. 16 to 17C is substantially the same as the transfer device 2000 of FIGS. 10 and 11 except that an optical system 3400 further includes a pitch correction unit 3420, so that a redundant description will be omitted.

Referring to FIG. 15, in the fabricating method of the display device 1000 according to another exemplary embodiment of the present disclosure, a step S800 of checking whether an interval between the plurality of light LI, that is, a pitch between the plurality of light LI and a pitch between the plurality of micro LEDs (ED) are equal to each other, a step S810 of changing the pitch between the plurality of light LI if the pitches are not equal, and a step S820 of rechecking whether the pitch between the plurality of light LI and the pitch between the plurality of micro LEDs (ED) are equal to each other may be further included between the step S200 of preparing a recipe and the step S300 of moving the wafer WF to a transfer position.

For example, after the step S200 of preparing a recipe, the step S800 of checking whether a pitch between the plurality of light LI and a pitch between the plurality of micro LEDs (ED) on the wafer are equal to each other may be performed. For example, if the pitch between the plurality of micro LEDs (ED) is X, it may be checked whether a pitch between the plurality of light LI which passes through the optical system 3400 to be finally irradiated on the wafer WF is X.

If the pitch between the plurality of micro LEDs (ED) and the pitch between the plurality of light LI are equal, the wafer WF moves to the transfer position to perform the transfer process.

In contrast, if the pitch between the plurality of micro LEDs (ED) and the pitch between the plurality of light LI are not equal, the step S810 of changing a pitch of the plurality of light LI which is irradiated from the optical system 3400 onto the wafer WF and the step S820 of rechecking whether the pitch between the plurality of micro LEDs (ED) and the pitch between the plurality of light LI are equal may be performed. In this case, a magnification of the plurality of light LI which is irradiated onto the wafer WF is changed using the pitch correction unit 3420 of the transfer device 3000 to adjust a pitch between the plurality of light LI, that is, an interval between the plurality of light LI.

Referring to FIG. 16, the optical system 3400 of the transfer device 3000 according to another exemplary embodiment of the present disclosure may further include a pitch correction unit 3420. The pitch correction unit 3420 may be a device for adjusting an interval between the plurality of light LI which passes through the digital mirror device 2300 and the optical system 340 to be directed to the wafer WF, that is, a pitch between the plurality of light LI. For example, if an interval of the plurality of light LI which passes through the digital mirror device 2300 and the optical system 340 to be irradiated onto the wafer WF is not equal to the interval of the plurality of micro LEDs (ED), the micro LED (ED) is not separated from the wafer WF. Therefore, the interval of the plurality of light LI which is irradiated onto the wafer WF may be adjusted using the pitch correction unit 3420 to correspond to one to one or integer multiple of the interval of the plurality of micro LEDs (ED).

Referring to FIGS. 17A to 17C, the pitch correction unit 3420 includes various lenses to adjust the interval of the plurality of light LI. For example, the pitch correction unit 3420 may include a third lens LS3 with a flat top surface and a concave bottom surface, a fourth lens LS4 with both convex surfaces, and a fifth lens LS5 with a concave top surface and a flat bottom surface. Further, the plurality of light LI which passes through the digital mirror device 2300 and the position correction unit 2410 to be incident onto the pitch correction unit 3420 sequentially passes through the third lens LS3, the fourth lens LS4, and the fifth lens LS5 to change the interval.

First, the plurality of light LI passes through the third lens LS3 to be refracted to increase the interval between the plurality of light LI. For example, the plurality of light LI may be incident to be perpendicular to the top surface of the third lens LS3. Further, light LI incident in the remaining area of the third lens LS3 excluding a center portion may be refracted from the concave bottom surface of the third lens LS3 and the light paths may be changed to be spaced apart from each other. That is, the plurality of light LI which vertically travels passes through the third lens LS3 and the light path is changed to radially spread. Accordingly, the plurality of light LI may be configured to move to be spaced apart from each other in an area between the third lens LS3 and the fourth lens LS4.

Next, light paths of the plurality of light LI which incident onto the fourth lens LS4 may be changed to a vertical direction in the fourth lens LS4. For example, the plurality of light LI which travels in an inclined direction may be refracted from the convex top surface of the fourth lens LS4 to be directed to the vertical direction again. In this case, the interval of the plurality of light LI on the top surface of the fourth lens LS4 and the interval of the plurality of light LI on the bottom surface of the fourth lens LS4 may be equal. Further, the plurality of light which travels vertically in the fourth lens LS4 may be refracted from the convex bottom surface of the fourth lens LS4 again. For example, the light LI which travels to the remaining portion of the bottom surface of the fourth lens LS4 excluding a center portion of the fourth lens LS4 is refracted from the convex bottom surface of the fourth lens LS4 so that the light paths may be changed to be close to each other. Accordingly, the light paths of the plurality of light LI which passes through the fourth lens LS4 may be changed to be collected toward one point. Accordingly, the plurality of light LI may be configured to move to be close to each other in an area between the fourth lens LS4 and the fifth lens LS5.

Finally, the plurality of light LI which is incident onto the fifth lens LS5 is refracted so that the light paths may be changed from the inclined direction to the vertical direction. For example, the plurality of light LI which slantly travels to be collected toward one point is refracted from the fifth lens LS5 in the vertical direction again so that the light paths may be changed to travel perpendicular to one surface of the wafer WF.

At this time, the interval between the plurality of light LI may be adjusted by adjusting an interval between the third lens LS3 and the fourth lens LS4 and the interval between the fourth lens LS4 and the fifth lens LS5. The larger the interval between the third lens LS3 and the fourth lens LS4, the larger the interval between the plurality of light LI and the larger the interval between the fourth lens LS4 and the fifth lens LS5, the smaller the interval between the plurality of light LI. As described above, in the area between the third lens LS3 and the fourth lens LS4, the plurality of light LI travels to radially spread and the interval between the plurality of light LI may increase. Therefore, the larger the interval between the third lens LS3 and the fourth lens LS4, the wider the plurality of light LI spreads so that the interval between the plurality of light LI may increase. Further, in the area between the fourth lens LS4 and the fifth lens LS5, the plurality of light LI travels to be collected to one point and the interval between the plurality of light LI may be reduced. Accordingly, the larger the interval between the fourth lens LS4 and the fifth lens LS5, the smaller the interval between the plurality of light L.

For example, referring to FIG. 17A, if a first interval D1 between the third lens LS3 and the fourth lens LS4 and a second interval D2 between the fourth lens LS4 and the fifth lens LS5 are equal, as much as the increased pitch between the plurality of light LI in an area between the third lens LS3 and the fourth lens LS4, the pitch between the plurality of light LI in an area between the fourth lens LS4 and the fifth lens LS5 may be reduced. Further, the pitches between the plurality of light LI before and after passing the pitch correction unit 3420 may be maintained to be the same. For example, if the first interval D1 between the third lens LS3 and the fourth lens LS4 and the second interval D2 between the fourth lens LS4 and the fifth lens LS5 are equal, the pitches between the plurality of light LI before and after passing the pitch correction unit 3420 may have the same value, a.

Referring to FIG. 17B, if a first interval D1′ between the third lens LS3 and the fourth lens LS4 is smaller than a second interval D2′ between the fourth lens LS4 and the fifth lens LS5, the pitch between the plurality of light LI may be reduced. For example, a reduced amount in the interval between the plurality of light LI in an area between the fourth lens LS4 and the fifth lens LS5 is larger than an increased amount in the interval between the plurality of light LI in an area between the third lens LS3 and the fourth lens LS4. Therefore, finally, the interval between the plurality of light LI may be reduced. For example, even though the pitch between the plurality of light LI before being incident onto the pitch correction unit 3420 is a, the pitch of the plurality of light LI may be reduced while passing through the pitch correction unit 3420 which is configured such that the first interval D1′ is smaller than the second interval D2′. Accordingly, the pitch of the plurality of light LI which passes through the pitch correction unit 3420 may be reduced from a to b.

Referring to FIG. 17C, if a first interval D1″ between the third lens LS3 and the fourth lens LS4 is larger than a second interval D2″ between the fourth lens LS4 and the fifth lens LS5, the pitch between the plurality of light LI may be increased. For example, an increased amount in the interval between the plurality of light LI in an area between the third lens LS3 and the fourth lens LS4 is larger than a reduced amount in the interval between the plurality of light LI in an area between the fourth lens LS4 and the fifth lens LS5. Therefore, finally, the interval between the plurality of light LI may be increased. For example, the pitch between the plurality of light LI before being incident onto the pitch correction unit 3420 is a and the pitch of the plurality of light LI may be increased while passing through the pitch correction unit 3420 which is configured such that the first interval D1″ is larger than the second interval D2″. Accordingly, the pitch of the plurality of light LI which passes through the pitch correction unit 3420 may be increased from a to c.

Accordingly, the pitch between the plurality of light LI may be adjusted by moving the position of the fourth lens LS4 disposed between the third lens LS3 and the fifth lens LS5. The fourth lens LS4 is disposed to be closer to the third lens LS3 to reduce the pitch between the plurality of light LI and the fourth lens LS4 is disposed to be closer to the fifth lens LS5 to increase the pitch between the plurality of light LI. Accordingly, the interval between the plurality of light LI and the interval between the plurality of micro LEDs (ED) are configured to be one to one or integer multiple by adjusting the position of the fourth lens LS4 to allow the plurality of light LI to be accurately irradiated onto each of the plurality of micro LEDs (ED).

In the meantime, even though in the present disclosure, it has been described that the pitch correction unit 3420 is configured by the third lens LS3, the fourth lens LS4, and the fifth lens LS5, the pitch correction unit 3420 may adjust the pitch of the plurality of light LI in various method, such as, further including an additional lens. However, the present disclosure is not limited thereto.

Accordingly, the transfer process may be performed after adjusting the pitch of the plurality of light so as to correspond to the pitch of the plurality of micro LEDs (ED) using the pitch correction unit 3420. In this case, the pitch of the plurality of light LI is freely changed so that the transfer process may be performed only with one transfer device 3000 so as to correspond to wafers WF and target substrates TS having various sizes. Accordingly, the transfer device 3000 according to another exemplary embodiment of the present disclosure includes the pitch correction unit 3420 to improve a degree of freedom of process and be used for a transfer process of wafers WF and target substrates TS with various disclosures.

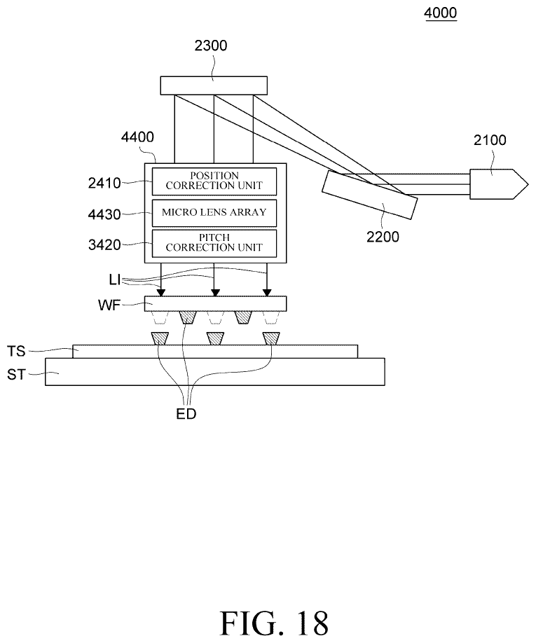

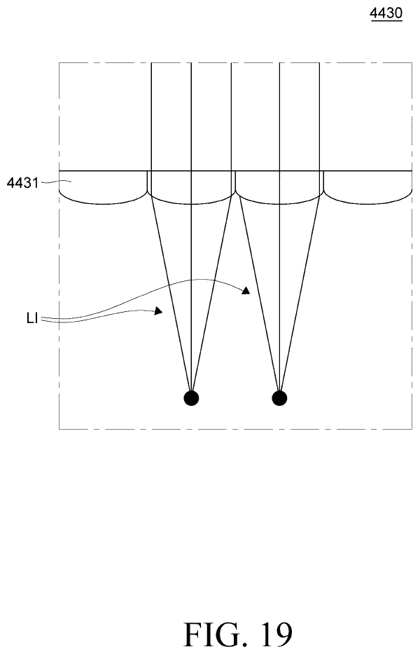

FIG. 18 is a diagram illustrating a transfer device according to still another exemplary embodiment of the present disclosure. FIG. 19 is a diagram illustrating a micro lens array of a transfer device according to still another exemplary embodiment of the present disclosure. A transfer device 4000 of FIGS. 18 and 19 is substantially the same as the transfer device 3000 of FIGS. 16 to 17C except that an optical system 4400 further includes a micro lens array 4430, so that a redundant description will be omitted.

Referring to FIGS. 18 and 19, the optical system 4400 of the transfer device 4000 according to still another exemplary embodiment of the present disclosure may further include a micro lens array 4430. The micro lens array 4430 is a device which adjusts a diameter of the plurality of light LI and may be configured with a structure in which a plurality of micro lenses 4431 with one convex surface is disposed. For example, if the diameter of each of the plurality of light LI which is incident from the optical system 4400 onto the wafer WF is larger than a size of each of the plurality of micro LEDs (ED), one light affects one micro LED (ED) to be transferred and the surrounding thereof. Therefore, a defect that a micro LED (ED) which is not a transfer target is transferred may occur. That is, a diameter of the plurality of light LI is larger than a size of the plurality of micro LEDs (ED), erroneous transfer defect may be easily caused and the accuracy of the transfer process is lowered so that a process yield may be reduced. Accordingly, the micro lens array 4430 may be configured to collect the plurality of light LI to reduce a diameter of each of the plurality of light LI.

For example, in the position correction unit 2410 of the optical system 4400, a diameter of each of the plurality of light LI and an interval between the plurality of light LI may be increased and the plurality of light LI with increased diameter and interval may be incident onto the micro lens array 4430. The plurality of light LI may be incident onto a plurality of micro lenses 4431 of the micro lens array 4430 and light LI incident onto one micro lens 4431 is refracted from a convex surface on the bottom of the micro lens 4431 to be collected on one spot. The plurality of light LI which passes through the micro lens array 4430 may be collected on one spot and a diameter of each of the plurality of light LI may be reduced. Accordingly, a diameter of each of the plurality of light LI is formed using the micro lens array 4430 to be at least equal to or smaller than the size of the micro LED (ED). The plurality of light LI is easily formed to have a micro size using the micro lens array 4430 so that each of the plurality of micro LEDs (ED) is more precisely transferred and the process yield may be improved.

The exemplary embodiments of the present disclosure can also be described as follows:

According to an aspect of the present disclosure, a transfer device configured to transfer a plurality of micro LEDs of a wafer onto a target substrate includes a light source configured to output light, a digital mirror device including a plurality of micro mirrors configured to reflect light from the light source, and an optical system configured to correct a plurality of light reflected from the plurality of micro mirrors to be transmitted to the wafer. Each of the plurality of light reflected from each of the plurality of micro mirrors is configured to be irradiated onto the wafer so as to correspond to each of the plurality of micro LEDs of the wafer.

Each of the plurality of micro mirrors may be configured to be independently rotatable.

The optical system may include a position correction unit, and the position correction unit may include a first lens with a concave top surface and a flat bottom surface, and a second lens which is disposed between the first lens and the wafer and has a flat top surface and a convex bottom surface.

An interval between the plurality of light which is incident onto the top surface of the first lens may be smaller than an interval between the plurality of light which is output to the bottom surface of the second lens.

A diameter of each the plurality of light which is incident onto the top surface of the first lens may be smaller than a diameter of each of the plurality of light which is output to the bottom surface of the second lens.

The optical system may further include a pitch correction unit, and the pitch correction unit may include a third lens with a flat top surface and a concave bottom surface, a fourth lens which is disposed between the third lens and the wafer and has convex top surface and bottom surface, and a fifth lens which is disposed between the fourth lens and the wafer and has a concave top surface and a flat bottom surface, and a first interval between the third lens and the fourth lens and a second interval between the fourth lens and the fifth lens may be configured to be variable.

In an area between the third lens and the fourth lens, the plurality of light may be configured to move to be spaced apart from each other and in an area between the fourth lens and the fifth lens, the plurality of light may be configured to move to be close to each other.

If the first interval and the second interval are equal, the interval between the plurality of light which is incident into the pitch correction unit may be equal to an interval between the plurality of light which passes through the pitch correction unit.

If the first interval is smaller than the second interval, the interval between the plurality of light which passes through the pitch correction unit may be smaller than an interval between the plurality of light which is incident into the pitch correction unit.

If the first interval is larger than the second interval, the interval between the plurality of light which passes through the pitch correction unit may be larger than an interval between the plurality of light which is incident into the pitch correction unit.

The optical system may include a micro lens array in which a plurality of micro lenses is disposed, and the micro lens array may be configured to reduce a diameter of each of the plurality of light.

The target substrate may include a display panel, and the display panel may include a substrate, a plurality of banks disposed on the substrate, and a plurality of first electrodes disposed on the plurality of banks, and the plurality of micro LEDs may be configured to be transferred onto the plurality of first electrodes.

Each of the plurality of micro LEDs may include an anode electrode, a first semiconductor layer disposed on the anode electrode, an active layer on the first semiconductor layer, a second semiconductor layer on the active layer, and a cathode electrode on the second semiconductor layer.

The display panel may further include a plurality of solder patterns disposed on the plurality of first electrodes and the plurality of solder patterns may be configured to electrically connect the anode electrode to each of the plurality of first electrodes using eutectic bonding.

The target substrate may include an interposer substrate.

According to an aspect of the present disclosure, a display device includes a substrate in which a plurality of pixels is defined, one or more pixel driving circuits disposed on the substrate, a plurality of micro LEDs which is disposed on the plurality of pixels and is electrically connected to the pixel driving circuit, a plurality of banks disposed below the plurality of micro LEDs, and a plurality of first electrodes which is disposed between the plurality of micro LEDs and the plurality of banks and is configured to electrically connect the pixel driving circuit and the plurality of micro LEDs.

The display device may further include a plurality of signal lines which electrically connects the plurality of first electrodes and the pixel driving circuit. The plurality of first electrodes and the plurality of signal lines may be configured to transmit an anode voltage output from the pixel driving circuit to the plurality of micro LEDs.

The display device may further include a plurality of solder patterns which is disposed between the plurality of first electrodes and the plurality of micro LEDs. The plurality of first electrodes and the anode electrodes of the plurality of micro LEDs may be electrically connected by eutectic bonding using the plurality of solder patterns.

The display device may further include a plurality of contact electrodes which is electrically connected to the pixel driving circuit, and one or more second electrodes which are disposed in the plurality of pixels and are electrically connected to the plurality of contact electrodes. The second electrodes and the plurality of contact electrodes may be configured to transmit a cathode voltage output from the pixel driving circuit to the plurality of micro LEDs.

The plurality of micro LEDs may be vertical type micro LEDs.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A transfer device configured to transfer a plurality of micro light emitting diodes (LEDs) of a wafer onto a target substrate, comprising:
a light source configured to output light;
a digital mirror device including a plurality of micro mirrors configured to reflect the light from the light source; and
an optical system configured to correct a plurality of light reflected from the plurality of micro mirrors to be transmitted to the wafer,
wherein each of the plurality of light reflected from each of the plurality of micro mirrors is irradiated onto the wafer so as to correspond to each of the plurality of micro LEDs of the wafer.

2. The transfer device according to claim 1, wherein each of the plurality of micro mirrors is configured to be independently rotatable.

3. The transfer device according to claim 1, wherein the optical system includes a position correction unit that includes:
a first lens with a concave top surface and a flat bottom surface; and
a second lens which is disposed between the first lens and the wafer and has a flat top surface and a convex bottom surface.

4. The transfer device according to claim 3, wherein an interval between the plurality of light which is incident onto the concave top surface of the first lens is smaller than an interval between the plurality of light which is output to the convex bottom surface of the second lens.

5. The transfer device according to claim 3, wherein a diameter of each the plurality of light which is incident onto the concave top surface of the first lens is smaller than a diameter of each of the plurality of light which is output to the convex bottom surface of the second lens.

6. The transfer device according to claim 1, wherein the optical system further includes a pitch correction unit that comprises:
a third lens with a flat top surface and a concave bottom surface;
a fourth lens between the third lens and the wafer, the fourth lens having a convex top surface and a convex bottom surface; and
a fifth lens between the fourth lens and the wafer, the fifth lens having a concave top surface and a flat bottom surface,
wherein a first interval between the third lens and the fourth lens and a second interval between the fourth lens and the fifth lens are configured to be variable.

7. The transfer device according to claim 6, wherein in an area between the third lens and the fourth lens, the plurality of light move to be spaced apart from each other and in an area between the fourth lens and the fifth lens, the plurality of light move to be close to each other.

8. The transfer device according to claim 6, wherein if the first interval and the second interval are equal, an interval between the plurality of light which is incident into the pitch correction unit is equal to an interval between the plurality of light which passes through the pitch correction unit.

9. The transfer device according to claim 6, wherein if the first interval is smaller than the second interval, an interval between the plurality of light which passes through the pitch correction unit is smaller than an interval between the plurality of light which is incident into the pitch correction unit.

10. The transfer device according to claim 6, wherein if the first interval is larger than the second interval, an interval between the plurality of light which passes through the pitch correction unit is larger than an interval between the plurality of light which is incident into the pitch correction unit.

11. The transfer device according to claim 1, wherein the optical system includes a micro lens array in which a plurality of micro lenses are disposed, and the micro lens array is configured to reduce a diameter of each of the plurality of light.

12. The transfer device according to claim 1, wherein the target substrate includes a display panel including:
a substrate;
a plurality of banks on the substrate; and
a plurality of first electrodes on the plurality of banks,
wherein the plurality of micro LEDs are transferred onto the plurality of first electrodes.

13. The transfer device according to claim 12, wherein each of the plurality of micro LEDs includes:
an anode electrode;
a first semiconductor layer on the anode electrode;
an active layer on the first semiconductor layer;
a second semiconductor layer on the active layer; and
a cathode electrode on the second semiconductor layer.

14. The transfer device according to claim 13, wherein the display panel further includes a plurality of solder patterns on the plurality of first electrodes,
wherein the plurality of solder patterns electrically connect the anode electrode to each of the plurality of first electrodes using eutectic bonding.

15. The transfer device according to claim 1, wherein the target substrate includes an interposer substrate.

16. A display device, comprising:
a substrate;
a plurality of pixels on the substrate;
one or more pixel driving circuits on the substrate;
a plurality of micro LEDs on the plurality of pixels, the plurality of micro LEDs electrically connected to the one or more pixel driving circuits;
a plurality of banks disposed below the plurality of micro LEDs; and
a plurality of first electrodes between the plurality of micro LEDs and the plurality of banks, the plurality of first electrodes electrically connecting the one or more pixel driving circuits and the plurality of micro LEDs.

17. The display device according to claim 16, further comprising:
a plurality of signal lines which electrically connect the plurality of first electrodes and the one or more pixel driving circuits,
wherein the plurality of first electrodes and the plurality of signal lines transmit an anode voltage output from the one or more pixel driving circuits to the plurality of micro LEDs.

18. The display device according to claim 17, further comprising:
a plurality of solder patterns between the plurality of first electrodes and the plurality of micro LEDs,
wherein the plurality of first electrodes and anode electrodes of the plurality of micro LEDs are electrically connected by eutectic bonding using the plurality of solder patterns.

19. The display device according to claim 16, further comprising:
a plurality of contact electrodes which are electrically connected to the one or more pixel driving circuits; and
one or more second electrodes which are disposed in the plurality of pixels, the one or more second electrodes electrically connected to the plurality of contact electrodes,
wherein the one or more second electrodes and the plurality of contact electrodes transmit a cathode voltage output from the one or more pixel driving circuits to the plurality of micro LEDs.

20. The display device according to claim 16, wherein the plurality of micro LEDs are vertical type micro LEDs.
